(19) United States
(12) Patent Application Publication
(10) Pub. No.: US 2026/0173941 A1
(43) Pub. Date: Jun. 18, 2026

(54) SURFACE MOUNT TECHNOLOGY USING INTERPOSER

(71) Applicant: Lenovo (Beijing) Limited, Beijing (CN)

(72) Inventors: Tadashi Kosuga, Kanagawa (JP); Tin-Lup Wong, Morrisville, NC (US); Yun Zhu, Beijing (CN); Hua Wang, Beijing (CN)

(73) Assignee: Lenovo (Beijing) Limited, Beijing (CN)

(21) Appl. No.: 18/853,228

(22) PCT Filed: Sep. 25, 2023
(86) PCT No.: PCT/CN2023/120960

§ 371 Date: Oct. 1, 2024

(51) Int. Cl. H10W 72/30; H10W 72/00; H10W 90/00

(52) U.S. Cl. CPC H10W 72/322; H10W 72/332; H10W 72/856; H10W 90/724; H10W 90/734

(57) ABSTRACT

A method of fabricating an electronic assembly includes: generating an array of voids in a sheet; forming an interposer by applying a first adhesive layer to a first surface of the sheet and a second adhesive layer to a second surface of the sheet; attaching, through the first adhesive layer, the interposer to a component having a ball grid array of solder balls; mounting, through the second adhesive layer, the interposer to a substrate having an array of contact pads whose pattern matches the ball grid array on the component; and forming an underfill between the component and the substrate by curing the first adhesive layer and second adhesive layer. The forming of the underfill includes connecting the solder balls to the contact pads by reflow soldering the solder balls at a temperature higher than a melting point of the solder balls.

### BACKGROUND

Surface mount technology (SMT) is a technique to fabricate electronic assemblies, in which components are mounted directly onto a surface of a substrate, for example a printed circuit board (PCB). The components are designed specifically to be directly mounted, rather than hardwired, onto the substrate for a vast majority of electronics. SMT allows for increased manufacturing automation which reduces cost and improves quality, such as higher component density and smaller components for mounting alongside better performance under pressure.

A ball grid array (BGA) technique is a surface mount method, mostly used for flip chips as the need for high-density mounting increased. The BGA includes an array of small-size metallic solder balls arranged on a bottom surface of a component. Correspondingly, a substrate includes an array of contact pads having a same pattern that matches the solder balls. The placement of component onto the substrate is realized by reflow soldering process, in which the solder balls are heated to melt using, for example, a reflow oven or by an infrared heater. The surface tension causes the molten solder balls to hold the component in alignment with the substrate at a certain separation distance. After the solder balls cool and solidify, solder joints are formed between the component and the substrate.

The solder balls that connect the substrate and the components are prone to fracturing when subject to mechanical and thermal stress, which in turn may cause a complete device failure. For example, bending, flexing, vibration, and a difference in coefficient of thermal expansion between the substrate and BGA may potentially cause the solder joints to fracture. There exists a need to develop a feasible and efficient technique that reinforces the solder joints to prevent failure.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In some aspects, the techniques described herein relate to a method of fabricating an electronic assembly, including: generating an array of voids on a sheet; applying a first adhesive layer to a first surface of the sheet and a second adhesive layer to a second surface of the sheet to form an interposer; attaching the interposer to a component, which includes a ball grid array of solder balls, through the first adhesive layer; mounting the interposer to a substrate, which includes an array of contact pads whose pattern matches the ball grid array on the component, through the second adhesive layer; and reflow soldering the solder balls at a temperature higher than a melting point of the solder balls, wherein, during the reflow soldering, the first adhesive layer and second adhesive layer solidify to form an underfill between the component and the substrate.

In some aspects, the techniques described herein relate to a method, further including aligning the voids with the ball grid array of the solder balls, such that each of the voids on the sheet accommodate one of the solder balls.

In some aspects, the techniques described herein relate to a method, wherein the array of the voids is generated before the applying of the first adhesive layer.

In some aspects, the techniques described herein relate to a method, wherein the array of the voids is generated after the applying of at least one of the first adhesive layer and the second adhesive layer.

In some aspects, the techniques described herein relate to a method, further including semi-curing at least one of the first adhesive layer and the second adhesive layer before mounting the interposer to the substrate.

In some aspects, the techniques described herein relate to a method, further including attaching a plurality of the interposers to one or more corners and/or one or more edges of the component.

In some aspects, the techniques described herein relate to a method, wherein the sheet is made of a material selected from ceramic, polymer, glass fiber, and insulated metal.

In some aspects, the techniques described herein relate to a method, wherein the voids are generated by drilling or wire weaving.

In some aspects, the techniques described herein relate to an electronic assembly, including: a component including a ball grid array of solder balls; a substrate including an array of contact pads whose pattern matches the ball grid array on the component; and an interposer between the component and the substrate, wherein the interposer includes a sheet having an array of voids, each void accommodating one of the solder balls; a first adhesive layer between the sheet layer and the component; and a second adhesive layer between the sheet layer and the substrate.

In some aspects, the techniques described herein relate to an electronic assembly, wherein the sheet is made of a material selected from ceramic, polymer, glass fiber, and insulated metal.

In some aspects, the techniques described herein relate to an electronic assembly, wherein the interposer is disposed at a corner or an edge of the component.

In some aspects, the techniques described herein relate to an electronic assembly, wherein a plurality of the interposers are disposed at one or more corners and/or one or more edges of the component.

Other aspects and advantages of the claimed subject matter will be apparent from the following description and the appended claims.

### BRIEF DESCRIPTION OF THE DRAWINGS

FIG. 1 shows a cross-sectional view of an electronic assembly fabricated by a conventional underfilling process.

FIG. 2 shows a cross-sectional view of an electronic assembly in accordance with one or more embodiments of the present disclosure.

FIG. 3 is a scheme illustrating a surface mount method for an electronic assembly in accordance with one or more embodiments of the present disclosure.

FIG. 4 is a cross-sectional view of an interposer in accordance with one or more embodiments of the present disclosure.

FIG. 5 is a cross-sectional view of an interposer in accordance with one or more embodiments of the present disclosure.

FIG. 6 is a flowchart of a surface mount method for an electronic assembly in accordance with one or more embodiments of the present disclosure.

### DETAILED DESCRIPTION

Specific embodiments of the present disclosure will now be described in detail below with reference to the accompanying drawings. Like elements in the various figures are denoted by like reference numerals for consistency.

In the following detailed description of embodiments of the disclosure, numerous specific details are set forth to provide a more thorough understanding of the invention. However, it will be apparent to one of ordinary skill in the art that the invention may be practiced without these specific details. In other instances, well-known features have not been described in detail to avoid unnecessarily complicating the description.

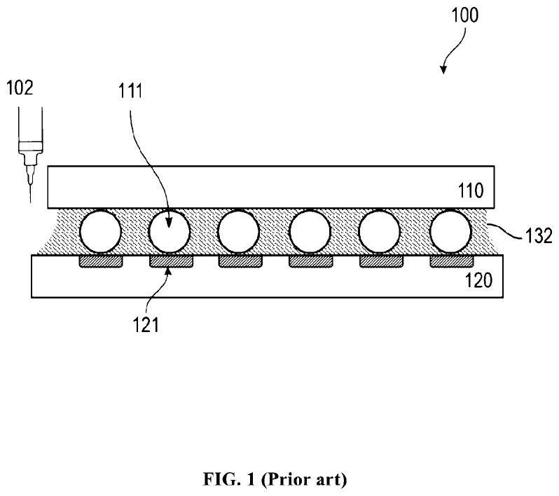

A “solder ball,” also referred to as “bump” or “solder bump,” is a ball of solder that provides contact between a component and a substrate, as well as between stacked components. The solder balls that connect the substrate and the components are prone to fracturing when subject to mechanical and thermal stress, which in turn may cause a complete device failure. An underfill may be applied after the soldering process to overcome this issue, as shown in the exemplary electronic assembly shown in FIG. 1. The electronic assembly 100 in FIG. 1 comprises a component 110, a substrate 120. The component 110 comprises an array of solder balls 111 (also referred to as BGA), soldered to a surface facing the substrate 120. The substrate 120 comprises an array of contact pads 121 having the same pattern as the solder balls 111. The component 110 and the substrate 120 are connected through a reflow soldering process, in which the solder balls 111 are heated to melt, for example using a reflow oven or by an infrared heater, such that surface tension causes the molten solder balls to hold the component 110 in alignment with the substrate 120 at certain separation distance defined by a size of the solder balls 111. After the solder balls cool and solidify, each contact pad 121 is in connection with a corresponding solder ball 111, such that the component and the substrate are electrically connected through the solder balls 111 and the contact pads 121.

An electrically insulating adhesive in a liquid phase may be dispensed at corners or edges of the component 110, using a dispenser 102. The dispenser may be a syringe, or more specifically, an automated syringe. The electrically insulating adhesive may flow to fill the gap between the component 110 and the substrate 120 under capillary effect. The adhesive is then thermally cured in place, forming an underfill 132 surrounding the solder balls and the contact pads that make up the electrical connection, resulting in a solid connection significantly less prone to fracturing. The formation of the underfill 132 also leaves little room for metal whiskers to form, eliminating the risk of short circuits.

In the example shown in FIG. 1, the formation of the underfill is performed after mounting of the component and the substrate, as well as the reflowing soldering of the solder balls. That is, the reflow soldering process and the formation of the underfill 132 are two separate processes in the fabrication of the electronic assembly shown in FIG. 1. On the other hand, the present disclosure provides a technique that enables one-step reflow soldering and underfill formation, including devices and methods utilizing a double-side coated interposer between the component and the substrate.

Specific embodiments of the electronic assemblies and surface mount methods will be described herein with reference to the accompanying figures. In the present disclosure, a thickness direction of the sheet is defined as a vertical direction Z. One direction perpendicular to the vertical direction Z indicates a direction X and another direction perpendicular to both directions of the vertical direction Z and the direction X indicates a direction Y. Along the vertical direction Z, the component side and the substrate side of the sheet respectively mean the upper (top) and lower (bottom) sides. A horizontal plane refers to the plane along direction X and direction Y, for example, a plane parallel to a top surface of the sheet. Moreover, a planar view means to view a target object from the vertical direction Z. A cross-sectional view, unless otherwise specified, refers to a sectional view of the object when cut apart along a plane in the vertical direction Z.

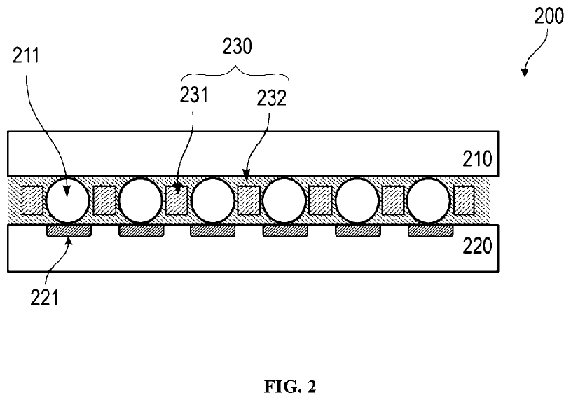

FIG. 2 shows an electronic assembly in accordance with one or more embodiments of the present disclosure. An “electronic assembly” in the present disclosure refers to a process of collecting, soldering, and/or integrating electronic components and circuits to carry out one or more tasks, as well as a product fabricated by such a process. The electronic assembly, as shown in FIG. 2, comprises a component 210, a substrate 220, and an interposer 230 between the component 210 and the substrate 220.

The component 210 comprises an array of solder balls 211, soldered to a bottom surface facing the substrate 220. The component 210 may be an electronic component, which can be any basic discrete device or physical entity in an electronic system used to affect electrons and/or their associated fields, or an integrated circuit (IC) component, which is an assembly of electronic components on a flat semiconductor material (e.g., a silicon wafer) connected together to achieve a common goal. Examples of the component 210 may include resistors, capacitors, inductors, discrete semiconductors, and integrated circuits. In one or more embodiments, the component 210 may be a microprocessor, for example, a central processing unit.

The solder balls 211 are solid metal spheres, with a diameter varying based on component design, depending on a desired separation distance to prevent bridging defects or shorts and/or a desired density of electronics to ensure high performance. The diameter of the solder balls 211 may range from about 100 μm to about 1000 μm, or from about 200 μm to about 800 μm. The solder balls 211 may be made of metal or metal alloy and may comprise, for example, tin (Sn), silver (Ag), copper (Cu), bismuth (Bi), and a combination thereof.

The substrate 220 is a supporting base on which the components and their connections are built. The substrate 220 may be silicon, doped or undoped, or an active layer of a silicon-on-insulator (SOI) substrate. The substrate may include semiconductor materials, such as germanium, silicon carbide, gallium arsenic, gallium phosphide, indium phosphide, indium arsenide, indium antimonide alloy semiconductor, or combinations thereof. The substrate may also include conductive layers, each designed with a pattern of traces, planes, or other features printed or etched on conductive material. Components on the substrate may be interconnected by, for example, metallization patterns in one or more dielectric layers to form an integrated circuit. In one or more embodiments, the substrate may be a printed circuit board (PCB).

The substrate 220 comprises an array of contact pads 221 that have the same pattern as the solder balls 211. The contact pads 221 may be made of metal or metal alloy, for example, tin (Sn), silver (Ag), gold (Au), copper (Cu), nickel (Ni), palladium (Pd), or a combination thereof. When joint together by reflow soldering, the solder joint formed by connected solder balls 211 and contact pads 221 electrically connect the component and the substrate.

The interposer 230 comprises a sheet 231 and an underfill 232. The interposer 230 provides advantageous effects in strengthening the solder joints, reinforcing the electronic assembly's resistance, absorbing the thermal expansion mismatch between the component and the substrate, so as to avoid fracturing when subject to mechanical and thermal stress. The sheet 231 has a planar shape, with a plurality of voids each accommodating one solder ball 211. In other words, the voids in the sheet 231 have the same pattern as the solder balls, within an area of the sheet 231. The sheet 231 may be made of a rigid material, for example, ceramic, polymer (e.g., polyimide, epoxy resin), glass fiber, insulated metal (e.g., stainless steel), and a combination thereof. In one or more embodiments, the sheet 231 may be made of a prepreg material, such as glass fiber with semi-cured resin. The sheet 231 is non-conductive.

The underfill 232 is an adhesive material that has flowability under room temperature or low temperature and cures under elevated temperatures to form a uniform and void-free layer. The underfill may be a polymer, for example, epoxy, silicone, and acrylic. The underfill may be in glue form or in film form. The underfill 232 may include one or more adhesives, for example, a first adhesive mainly distributed between the sheet 231 and the component 210 and a second adhesive mainly distributed between the sheet 231 and the substrate 220. In between solder balls and contact pads, the underfill may comprise a mixture of the first and second adhesives.

In one or more embodiments, the first adhesive and the second adhesive are both single component adhesive and are cured thermally. For example, each of the first adhesive and the second adhesive is composed of an epoxy resin. In other embodiments, one of the first adhesive and the second adhesive is a twin-component adhesive, which is semi-cured under ultraviolet light and cured thermally, while the other one is a single component adhesive which is cured thermally. For example, the first adhesive may be composed of an acrylic acid and the second adhesive may be composed of an epoxy resin.

The electronic assembly 200 may include a plurality of the interposers described herein. In some implementations, the interposers may be disposed at corners or edges of the electronic assembly, because these areas may experience a higher stress, mechanically or thermally.

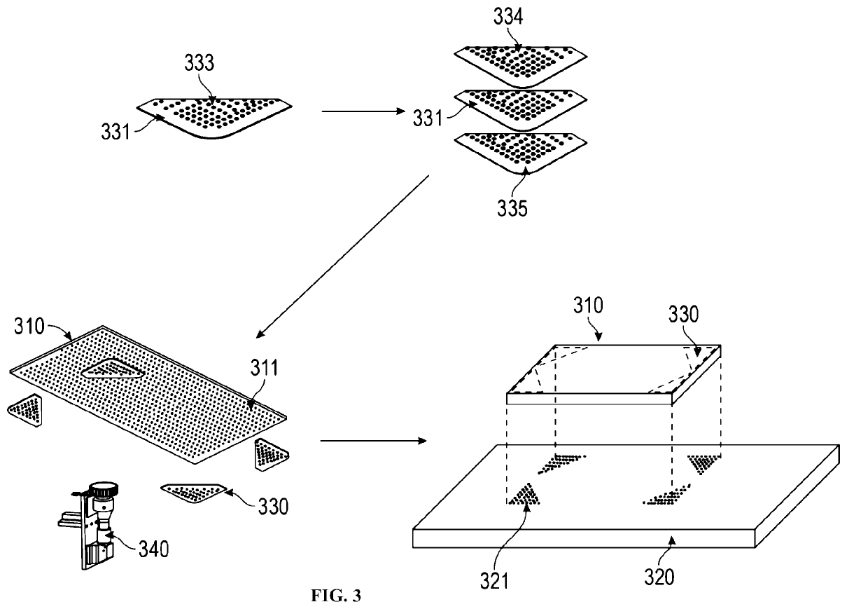

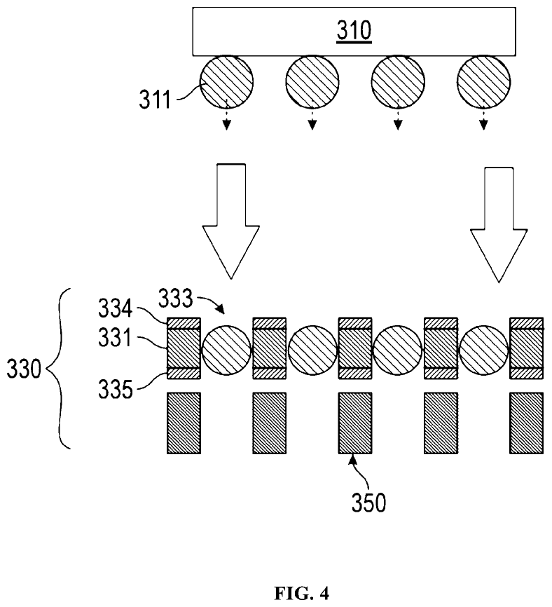

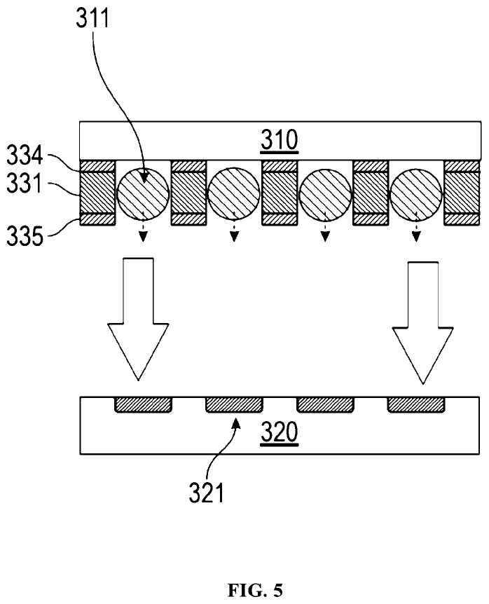

The surface mount method for an electronic assembly in accordance with one or more embodiments of the present disclosure is shown in the scheme of FIG. 3. FIGS. 4 and 5 show cross-sectional views of the interposer during processes in the surface mount method. The fabrication of the electronic assembly starts with a sheet 331 having an array of voids 333. The sheet 331 may be made of a rigid material such as ceramic, polymer (e.g., polyimide, epoxy resin), glass fiber, and insulated metal (e.g., stainless steel). A pattern of the voids 333 is generated to match the solder balls 311 on corresponding component 310. Each void 333 may have a round shape and a diameter that is slightly larger than a diameter of each solder ball 311. In one or more embodiments, the array of voids 333, which are in the form of thorough holes, may be generated by drilling (or punching). For example, in some implementations, the sheet is a non-conductive sheet without voids, and the array of voids is generated by drilling the non-conductive sheet using a laser. In other embodiments, the sheet 331 may be a mesh, prepared by wire weaving or other mesh manufacture techniques. For example, the sheet may be a glass fiber mesh, or a stainless steel mesh coated with an insulation material (e.g., a paint of a polymer, such as polyimide). The insulation material may be coated by any known technique in the art, for example, physical vapor deposition (PVD) or spray coating.

An interposer 330 is formed by applying a first adhesive layer 334 to an upper surface of the sheet 331 and a second adhesive layer to a lower surface of the sheet 331. The first adhesive layer 334 and the second adhesive layer 335 may be applied one after another or simultaneously using any known technique in the art. In some implementations, an adhesive that is in a liquid phase may be applied by drop casting, spray coating, or electrodeposition. In some implementations, an adhesive may be applied by immersing the sheet in an adhesive solution, followed by a semi-curing process to immobilize the adhesive. The semi-cured adhesive may have some flowability but does not flow freely. For example, the semi-cured adhesive may be in a gel state, such that it does not drop or misalign in the subsequent processes. In some implementations, an adhesive is applied simply by dispensing droplets on a surface of the sheet. In some implementations, an adhesive in a film form may be applied directly.

A thickness of the sheet 331 may range from about 0.05 mm to about 0.6 mm. A thickness of the first adhesive layer 334 may range from about 20 μm to about 300 μm. A thickness of the second adhesive layer 335 may range from about 20 μm to about 300 μm. A total thickness of the sheet and the two adhesive layers may not exceed a height of the solder balls before subsequent mounting and may not exceed a height of the solder joints after reflow soldering. The thickness of the sheet may be controlled by rolling the sheet before applying the first adhesive layer and/or the second adhesive layer. Alternatively, the rolling may be performed after applying the first adhesive layer and/or the second adhesive layer, such that a total thickness of the interposer is controlled.

In one or more embodiments, the interposer 330 is fabricated according to an order shown in FIG. 3, in which the first adhesive layer 334 and the second adhesive layer 335 are applied to the sheet 331 with voids 333. However, one having ordinary skill in the art would recognize that present disclosure is not limited thereby and that the order may be changed as needed. In one or more embodiments, the voids may be generated (e.g., by drilling) after applying the first adhesive layer to the sheet, or after applying the first adhesive layer and the second adhesive layer to the sheet. For example, in some implementations when the sheet is a glass fiber mesh, the first adhesive layer and the second adhesive layer may be applied to the mesh surface before laser drilling. In some implementations, the sheet may be made of a stainless steel mesh coated with an insulation (non-conductive) material, and voids in the insulated stainless steel mesh may be customized by electroforming followed by laser drilling.

The interposer 330, having the sheet and adhesive layers vertically stacked together, is then attached to a component 310 through the first adhesive layer 334. In the example shown in FIG. 3, four pieces of the interposer 330 are attached at the four corners of the component 310, because corners and/or edges may experience a higher stress, mechanically or thermally. However, one having ordinary skill in the art would recognize that the present disclosure is not limited to the example shown in the figure. A shape, size, disposition, and number of interposers may be subject to change in practical applications. For example, two pieces of the interposer may be used to cover four corners and two edges of the component. One piece of the interposer may be used to cover four edges around a perimeter of the component, any desired area of the component, or an entirety of the component.

A cross-sectional view of the interposer during attachment is shown in FIG. 4. As shown in FIGS. 3 and 4, an alignment may be performed before attachment to ensure that the positions of the solder balls 311 match with the voids 333, with each void accommodating one solder ball after the attachment. An alignment system 340, for example a charge-coupled device (CCD) auto alignment camera, may be used to check one or more markers on the interposer (e.g., on one of the adhesive layers) or an outline of the interposer 330. A pick-and-place tool may be used to pick up the component 310 and place the component 310 in place under instructions of the alignment system. A fixture 350 may be used to support the interposer 330 during attachment. In one or more embodiments, a release film may be used to temporarily cover the second adhesive layer when attaching the first adhesive layer. The fixture 350 may be designed to have a same pattern of voids as the interposer 330. A pressure may be applied to the component 310 when attaching the component 310 and the interposers 330. As a result, a bottom surface of the component 310 is attached to the interposer 330 through the first adhesive layer 334, with the solder balls 311 accommodated in the voids 333.

A combined structure of the interposer 330 and the component 310 may be mounted to the substrate 320. A cross-sectional view of the interposer during the mounting process is shown in FIG. 5. After attachment of the component and mounting to the substrate, the first adhesive layer 334 and the second adhesive layer 335 flow to fill the gap between the component 310 and the substrate 320. In one or more embodiments, the first adhesive is semi-cured to a gel state after the attachment and before the mounting, so as to prevent dropping or misalignment of the first adhesive layer when mounting or moving the combined structure and mitigate handling risk. An elevated temperature used for precuring may range from about 80 to about 140° C. for about 1 to about 30 minutes.

The combined structure of the interposer 330 and the component 310 is fixed to the substrate 320 through reflow soldering. A heating system, such as a reflow oven, may be used to provide elevated temperatures in the reflow soldering process. The reflow soldering process may include a first stage when the temperature is increased from about room temperature to an elevated temperature above a melting point of the solder balls 311, a second stage when the temperature is maintained at the elevated temperature for a certain period, and a third stage of cooling. In the first stage, the temperature may increase at a rate of 1-5° C. per second, or at a rate of 1-3° C. per second. The elevated temperature may be in a range of about 140° C. to about 250° C. The solder balls 311 may melt under the elevated temperature, and surface tension causes the molten solder balls to hold the component 110 in alignment with the substrate 120 at a certain separation distance. After the solder balls 311 cool and solidify, each contact pad 321 is in connection with a corresponding solder ball 311, such that the component 310 and the substrate 320 are electrically connected through the solder balls 311 and the contact pads 321.

At the time of reflow soldering, the first adhesive layer 334 and the second adhesive layer 335 are also cured under the elevated temperature to form the underfill between the component 310 and the substrate 320. That is, the formation of underfill and the reflow soldering are realized in the same step.

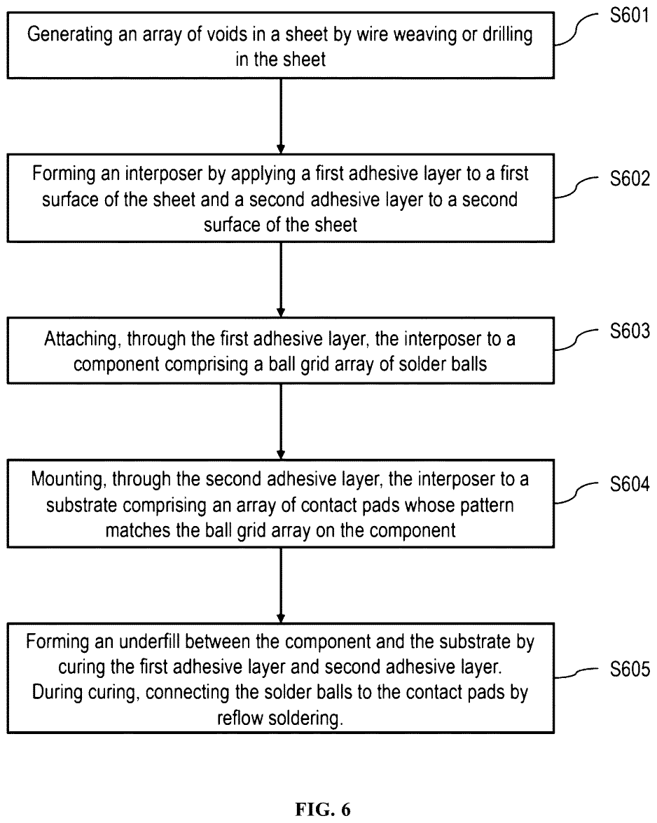

The flowchart in FIG. 6 shows the surface mount method described in one or more embodiments of the present disclosure. The surface mount method may include step S601, generating an array of voids in a sheet. The sheet may be made of a material selected from ceramic, polymer, glass fiber, and insulated metal. The voids may be prepared by wire weaving or drilling in the sheet.

In one or more embodiments, the surface mount method may include step S602, forming an interposer by applying a first adhesive layer to a first surface of the sheet and a second adhesive layer to a second surface of the sheet. The first adhesive layer and the second adhesive layer may be applied by any known technique in the art, for example, drop casting, spray coating, electrodeposition, immersion in adhesive solution, and droplets dispensing. The generating of voids in S601 may be performed before the forming of the interpose in S602. Alternatively, the generating of voids may be performed after applying the first adhesive layer and before applying the second adhesive layer, or may be performed after applying the first adhesive layer and the second adhesive layer.

In one or more embodiments, the surface mount method may include step S603, attaching, through the first adhesive layer, the interposer to a component comprising a ball grid array of solder balls. To ensure that each of the voids on the sheet corresponds to each of the solder balls, the surface mount method may include aligning the voids with the ball grid array of the solder balls, such that each of the voids on the sheet accommodate one of the solder balls.

In one or more embodiments, the surface mount method may include step S604, mounting, through the second adhesive layer, the interposer to a substrate comprising an array of contact pads whose pattern matches the ball grid array on the component. In one or more embodiments, at least one of the first adhesive layer and the second adhesive layer is semi-cured before mounting the interposer to the substrate. The first adhesive layer and/or second adhesive layer, either semi-cured or not before mounting, may still have flowability at the time of the mounting so as to flow and fill the gap between the component and the substrate.

In one or more embodiments, the surface mount method may include step S605, forming an underfill between the component and the substrate by curing the first adhesive layer and second adhesive layer that has filled the gap in between. During the process of curing, the solder balls are connected to the contact pads by reflow soldering the solder balls at a temperature higher than a melting point of the solder balls. Both the curing and the reflow soldering are performed at elevated temperatures and are performed in one step.

One or more embodiments described in the present disclosure provide electronic assemblies and surface mount methods that realize reflow soldering and underfill formation in a single step. By utilizing a double-side coated interposer between the component and the substrate, the formation of underfill may be performed at the time of reflow soldering. Thus, an underfilling process after reflow soldering may be eliminated. The interposer may provide rigidity to the assembly and reduces the possibility of failure caused by thermal and/or mechanical stress.

While only a few configurations are shown in the accompanying figures, one having ordinary skill in the art would recognize that the present disclosure may be adapted to a variety of shape, size, materials, and disposition, and that many modifications are possible in the example embodiments without materially departing from this invention. Accordingly, all such modifications are intended to be included within the scope of this disclosure as defined in the following claims.

1. A method of fabricating an electronic assembly, comprising:
generating an array of voids in a sheet;
forming an interposer by applying a first adhesive layer to a first surface of the sheet and a second adhesive layer to a second surface of the sheet;
attaching, through the first adhesive layer, the interposer to a component comprising a ball grid array of solder balls;
mounting, through the second adhesive layer, the interposer to a substrate comprising an array of contact pads whose pattern matches the ball grid array on the component; and
forming an underfill between the component and the substrate by curing the first adhesive layer and second adhesive layer, wherein the forming of the underfill comprises connecting the solder balls to the contact pads by reflow soldering the solder balls at a temperature higher than a melting point of the solder balls.

2. The method of claim 1, further comprising aligning the voids with the ball grid array of the solder balls, such that each of the voids on the sheet accommodate one of the solder balls.

3. The method of claim 1, wherein the array of the voids is generated in the sheet before the applying of the first adhesive layer.

4. The method of claim 1, wherein the array of the voids is generated after the applying of at least one of the first adhesive layer and the second adhesive layer.

5. The method of claim 1, wherein the array of the voids is generated by drilling or wire weaving.

6. The method of claim 1, further comprising semi-curing at least one of the first adhesive layer and the second adhesive layer before mounting the interposer to the substrate.

7. The method of claim 1, further comprising attaching additional interposers to one or more corners and/or one or more edges of the component.

8. The method of claim 1, wherein the sheet is made of a material selected from ceramic, polymer, glass fiber, and insulated metal.

9. An electronic assembly, comprising:
a component comprising a ball grid array of solder balls;
a substrate comprising an array of contact pads whose pattern matches the ball grid array on the component; and
an interposer between the component and the substrate,
wherein the interposer comprises:
a sheet having an array of voids, each void accommodating one of the solder balls; and
an underfill that fills a gap between the component and the substrate and includes a first adhesive between the sheet and the component and a second adhesive layer between the sheet and the substrate.

10. The electronic assembly of claim 9, wherein the sheet is made of a material selected from ceramic, polymer, glass fiber, and insulated metal.

11. The electronic assembly of claim 9, wherein the interposer is disposed at a corner or an edge of the component.

12. The electronic assembly of claim 9, wherein a plurality of the interposers are disposed at one or more corners and/or one or more edges of the component.
